(19) United States
(12) Patent Application Publication
(10) Pub. No.: US 2014/0313840 A1
(43) Pub. Date: Oct. 23, 2014

(54) INTEGRATED CIRCUIT AND MEMORY DEVICE

(71) Applicant: SK hynix Inc., Gyeonggi-do (KR)

(72) Inventor: Jeong-Tae HWANG, Gyeonggi-do (KR)

(73) Assignee: SK hynix Inc., Gyeonggi-do (KR)

(21) Appl. No.: 13/969,157

(22) Filed: Aug. 16, 2013

(30) Foreign Application Priority Data
Apr. 17, 2013 (KR) 10-2013-0042205

(51) Int. Cl. G11C 5/14; G11C 29/04

(52) U.S. Cl. CPC G11C 5/148; G11C 29/04
USPC 365/200; 365/226

(57) ABSTRACT

An integrated circuit includes a programmable storage unit suitable for operating with a plurality of powers and outputting stored data in response to a boot-up signal, a register unit suitable for storing the data outputted from the programmable storage unit, a internal circuit suitable for operating by using the data stored in the register unit, a voltage detection unit suitable for activating a power stabilization signal when levels of the plurality of powers are stabilized, and a boot-up control unit suitable for counting a number of activations of a periodic wave from a time of an activation of the power stabilization signal and activating the boot-up signal when the counted number reaches a predetermined number.

### CROSS-REFERENCE TO RELATED APPLICATIONS

The present application claims priority of Korean Patent Application No. 10-2013-0042205, filed on Apr. 17, 2013, which is incorporated herein by reference in its entirety.

### BACKGROUND

1. Field

Exemplary embodiments of the present invention relate to an integrated circuit and a memory device, and more particularly, to a boot-up operation for an integrated circuit.

2. Description of the Related Art

FIG. 1 is a block diagram illustrating a conventional memory device performing a repair operation.

Referring to FIG. 1, the memory device includes a cell array 110 that includes a plurality of memory cells, a row circuit 120 that activates a row (or a word line) selected by a row address R_ADD, and a column circuit 130 that accesses, for example, reads or writes, data of a column (or a bit line) selected by a column address C_ADD.

A row fuse circuit 140 stores a row address corresponding to a defective memory cell within the cell array 110 as a repair row address REPAIR_R_ADD. A row comparison unit 150 compares the repair row address REPAIR_R_ADD stored in the row fuse circuit 140 to a row address R_ADD inputted from the outside of the memory device. When the repair row address REPAIR_R_ADD is identical with the row address R_ADD, the row comparison unit 150 controls the row circuit 120 to activate a redundancy row (or a redundancy word line) instead of a row designated with the row address R_ADD

The column fuse circuit 160 stores a column address corresponding to a defective memory cell within the cell array 110 as a repair column address REPAIR_C_ADD. The column comparison unit 170 compares the repair column address REPAIR_C_ADD stored in the column fuse circuit 160 to a column address C_ADD inputted from the outside of the memory device. When the repair column address REPAIR_C_ADD is identical with the column address C_ADD, the column comparison unit 170 controls the column circuit 130 to access a redundancy column (or a redundancy bit line) instead of a column designated with the column address C_ADD. For reference, in the FIG. 1, “DATA” denotes data or data pads.

In general, laser fuses are mainly used in the fuse circuits 140 and 160. The laser fuse stores a logic high data or a logic low data depending on whether the fuse is cut or not. Programming of the laser fuse may be performed in a wafer state, but the programming of the fuse may not be performed after a wafer is mounted inside a package. Furthermore, the laser fuses may not be designed in a small circuit area due to the limit in a line pitch.

In order to overcome such concerns, as disclosed in U.S. Pat. No. 6,904,751, U.S. Pat. No. 6,777,757, U.S. Pat. No. 6,667,902, U.S. Pat. No. 7,173,851, and U.S. Pat. No. 7,269,047, a memory device includes a programmable storage unit such as an e-fuse array circuit, a NAND flash memory, a NOR flash memory, an erasable programmable read only memory (EPROM), an electrically erasable programmable read only memory (EEPROM), a ferroelectric RAM (FRAM), a magnetoresistive RAM (MRAM) a spin transfer torque MRAM (STT-MRAM), a resistive RAM (ReRAM), or a phase change RAM (PCRAM). Repair information, including, for example, fail addresses, is stored in the programmable storage unit.

FIG. 2 is a block diagram illustrating a conventional memory device including a programmable storage unit for storing repair information.

Referring to FIG. 2, the memory device includes a plurality of memory banks BK0 to BK3, a plurality of register units 210_0 to 210_3 provided for the respective memory banks BK0 to BK3 to store repair information, and a programmable storage unit 201.

The fuse circuits 140 and 160 shown in FIG. 1 are substituted with the programmable storage unit 201. Here, the repair information corresponding to all of the memory banks BK0 to BK3, including, for example, fail addresses, is stored. The programmable storage unit 201 may include one of an e-fuse array circuit, a NAND flash memory, a NOR flash memory, an EPROM, an EEPROM, an FRAM an MRAM, a STT-MRAM, a ReRAM, and a PCRAM.

The plurality of register units 210_0 to 210_3 provided in the memory banks BK0 to BK3, respectively, may store the repair information regarding the corresponding memory banks. That is, the register unit 210_0 may store the repair information regarding the memory bank BK0 and the register unit 210_2 may store the repair information regarding the memory bank BK2. The plurality of register units 210_0 to 210_3 each may include latch circuits and store the repair information only while power is supplied. The repair information to be stored in the plurality of register units 210_0 to 210_3 is transmitted from the programmable storage unit 201. The programmable storage unit 201 transmits the repair information stored from the time of activation of a boot-up enable signal BOOTEN to the plurality of register units 210_0 to 210_3.

Since the programmable storage unit 201 is configured in an array form, it takes some time to call for internally stored data. Since calling for data promptly may not be performed, it may not be possible to perform a repair operation immediately using the data stored in the programmable storage unit 201. Therefore, the repair information stored in the programmable storage unit 201 is transmitted and stored in the plurality of register units 210_0 to 210_3. Then, the data stored in the plurality of register units 210_0 to 210_3 is used for the repair operation of the memory banks BK0 to BK3. A process of transmitting the repair information stored in the programmable storage unit 201 to the plurality of register units 210_0 to 210_3 is referred to as a boot-up operation. When a boot-up operation is completed, the memory device may repair a defective cell and start performing a normal operation.

As described above, in the memory device that stores the repair information using the programmable storage unit 201, a boot-up operation is to be performed before a normal operation, for example, read operation and write operation, of the memory device. In the related art, methods for causing a boot-up operation to start in response to activation of an initial signal, for example, a reset signal, applied to the memory device have been used. However, the initial signal may not be used according to an application for the memory device in some cases. Further, there may be an interval at which a boot-up operation may be performed even before the initial signal is activated. Accordingly, it may be necessary to provide a technology for controlling a boot-up operation such that the boot-up operation starts as early as possible.

### SUMMARY

Various embodiments are directed to an integrated circuit or a memory device capable of perform a boot-up operation at an optimum time.

In an embodiment, an integrated circuit may include a programmable storage unit suitable for operating with a plurality of powers and outputting stored data in response to a boot-up signal, a register unit suitable for storing the data outputted from the programmable storage unit, a internal circuit suitable for operating by using the data stored in the register unit, a voltage detection unit suitable for activating a power stabilization signal when levels of the plurality of powers are stabilized, and a boot-up control unit suitable for counting a number of activations of a periodic wave from a time of an activation of the power stabilization signal and activating the boot-up signal when the counted number reaches a predetermined number.

In another embodiment, a memory device may include a programmable storage unit suitable for operating with a plurality of powers and outputting stored repair information in response to a boot-up signal, a plurality of register units suitable for storing the repair information outputted from the programmable storage unit, a plurality of memory banks having a plurality of normal cells and a plurality of redundancy cells, in which a defective cell included in the plurality of normal cells is substituted with one of the redundancy cells using the repair information stored in the respective register units, a voltage detection unit suitable for activating a power stabilization signal when levels of the plurality of powers are stabilized, and a boot-up control unit suitable for counting a number of activations of a periodic wave from a time of an activation of the power stabilization signal and activating the boot-up signal when the counted number reaches a predetermined number.

In another embodiment, an integrated circuit may include a programmable storage unit suitable for performing a boot-up operation using an internal voltage in response to a boot-up enable signal, a voltage detection unit suitable for detecting a level of the internal voltage to generate a power stabilization signal, and a boot-up control unit suitable for generating the boot-up enable signal by counting a predetermined number of cycles of a periodic wave having a predetermined frequency, in response to the power stabilization signal.

### BRIEF DESCRIPTION OF THE DRAWINGS

FIG. 1 is a block diagram illustrating a conventional memory device performing a repair operation,

FIG. 2 is a block diagram illustrating a conventional memory device including a programmable storage unit for storing repair information.

FIG. 3 is a block diagram illustrating a memory device according to an embodiment of the present invention.

FIG. 4 is a detailed diagram illustrating a boot-up control unit shown in FIG. 3.

FIG. 5 is a detailed diagram illustrating a voltage detection unit shown in FIG. 3.

FIG. 6 is a detailed diagram illustrating a first voltage detector shown in FIG. 5.

FIG. 7 is a detailed diagram illustrating a second voltage detector shown in FIG. 5.

FIG. 8 is a detailed diagram illustrating a third voltage detector shown in FIG. 5.

FIG. 9 is a detailed diagram illustrating the voltage detection unit shown in FIG. 3 according to another embodiment.

FIG. 10 is a block diagram illustrating an integrated circuit according to another embodiment of the present invention.

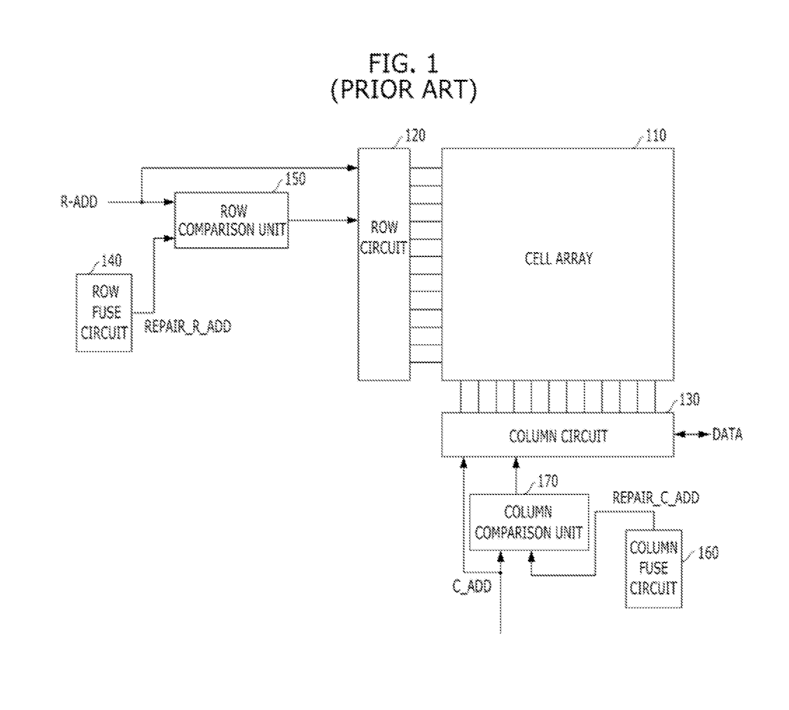

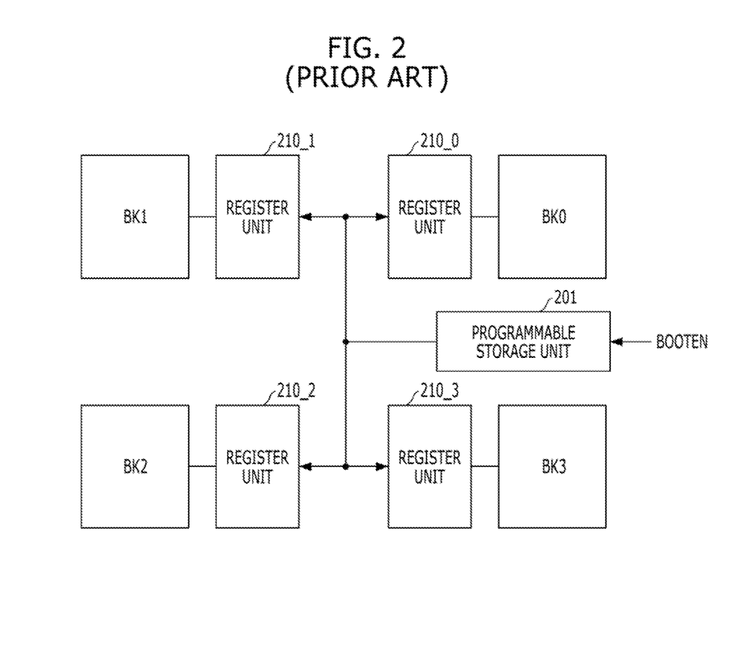

### DETAILED DESCRIPTION

Hereinafter, embodiments of the present invention will be described with reference to the accompanying drawings to make detailed description such that those skilled in the art may easily embody the technical spirit and essence of the present invention. In the description of the present invention, known configurations irrelevant to the gist of the present invention may be omitted. When reference numerals are given to constituent elements of each drawing, the same reference numerals are given to the same constituent elements although illustrated in the different drawings. Throughout the disclosure, reference numerals correspond directly to the like numbered parts in the various figures and embodiments of the present invention. It is also noted that in this specification, “connected/coupled” refers to one component not only directly coupling another component but also indirectly coupling another component through an intermediate component. In addition, singular form may include a plural form as long as it is not specifically mentioned in a sentence.

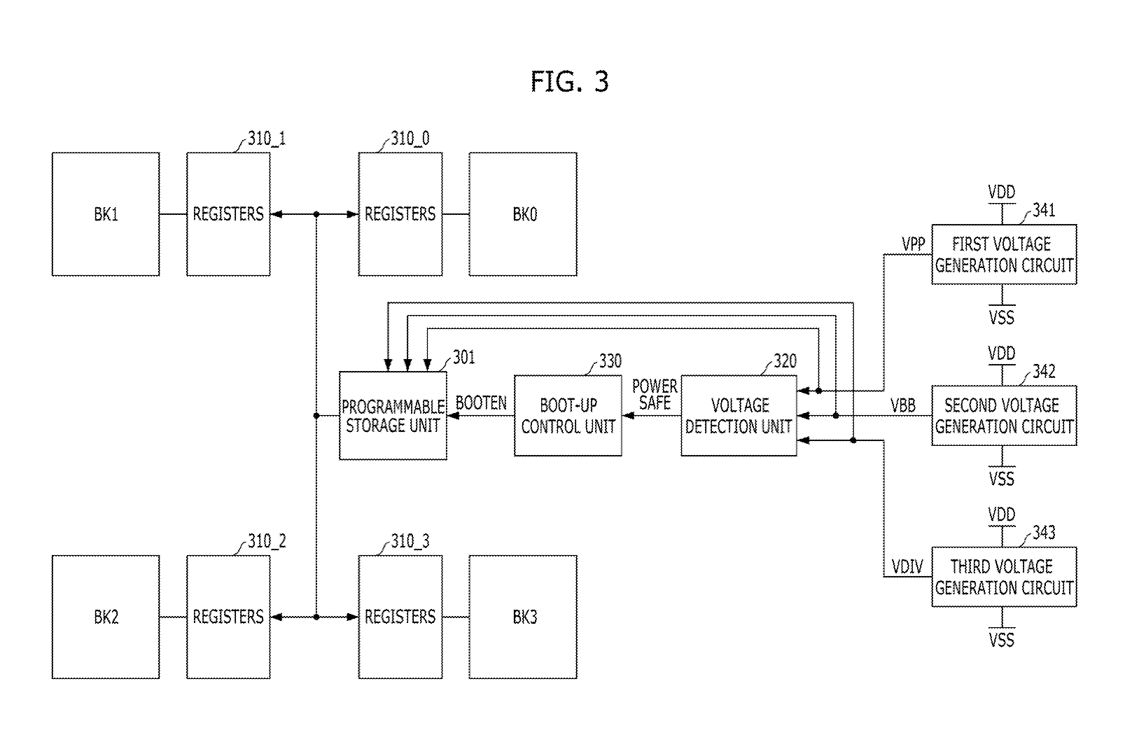

FIG. 3 is a block diagram illustrating a memory device according to an embodiment of the present invention.

Referring to FIG. 3, the memory device may include a programmable storage unit 301, a plurality of register units 310_0 to 310_3, a plurality of memory banks BK0 to BK3, a voltage detection unit 320, a boot-up control unit 330, and first to third voltage generation circuits 341 to 343.

Voltages to be inputted from the outside of the memory device include a source voltage VDD having a level of about 1.2 V to about 2.0 V and a ground voltage VSS. To operate the programmable storage unit 301, voltages with more various levels are necessary. For example, when the programmable storage unit 301 is an e-fuse array circuit, about 6 V is required to be ensured as a level difference between the highest voltage and the lowest voltage in order to program an e-fuse. When the programmable storage unit 301 is a flash memory, about 15 V to about 20 V is required to be ensured as a level difference between the highest voltage and the lowest voltage in order to perform programming and a reading operation. Accordingly, the programmable storage unit 301 also uses internal voltages (or internal powers) VPP, VBB, and VDIV generated by the first to third voltage generation circuits 341 to 343 in the memory device in addition to the source voltages VDD and VSS inputted from the outside of the memory device.

The first to third voltage generation circuits 341 to 343 generate the voltages VPP, VBB, and VDIV to be used in the programmable storage unit 301, using the source voltage VDD and the ground voltage VSS inputted from the outside of the memory device. The first voltage generation circuit 341 generates the boosted voltage VPP with a higher level than the source voltage VDD by pumping the source voltage VDD. The second voltage generation circuit 342 generates the negative voltage VBB with a lower level than the ground voltage VSS by pumping the ground voltage VSS. The third voltage generation circuit 343 generates a divided voltage VDIV with a level between the source voltage VDD and the ground voltage VSS by performing voltage division using the source voltage VDD and the ground voltage VSS. In the embodiment, the example has been described in which the programmable storage unit 301 uses the three voltages VPP, VBB, and VDIV generated inside in addition to the voltages VDD and VSS inputted from the outside of the memory device. However, the number and kinds of voltages to be used in the programmable storage unit 301 may, of course, be different according to the kind and design of the programmable storage unit 301.

The programmable storage unit 301 stores repair information corresponding to the memory banks BK0 to BK3, including, for example, fail addresses. The programmable storage unit 301 may be one of an e-fuse array circuit, a NAND flash memory, a NOR flash memory, an EPROM, an EEPROM, an FRAM, an MRAM, a STT-MRAM, a ReRAM and a PCRAM. The programmable storage unit 301 operates using the powers VDD, VSS, VPP, VBB, and VDIV. The programmable storage unit 301 starts transmitting the stored repair information to the plurality of register units 310_0 to 310_3 in response to activation of a boot-up enable signal BOOTEN. That is, the programmable storage unit 301 starts performing a boot-up operation in response to the activation of the boot-up enable signal BOOTED.

The plurality of register units 310_0 to 310_3 stores the repair information regarding the memory banks BK0 to BK3 corresponding to the own registers, respectively. The repair information is transmitted from the programmable storage unit 301 to the plurality of register units 310_0 to 310_3 and is stored when the boot-up operation is performed. The plurality of register units 310_0 to 310_3 may be configured to include latch circuits and retain information stored only while power is supplied to the memory device.

The memory banks BK0 to BK3 perform the repair operation of substituting a defective cell with a redundancy cell based on the repair information stored in the plurality of register units 310_0 to 310_3. The memory bank BK0 uses the repair information stored in the register unit 310_0. The memory bank BK2 uses the repair information stored in the register unit 310_2.

The voltage detection unit 320 activates a power stabilization signal POWER_SAFE, when the levels of the powers VDD, VPP, VBB, and VDIV used in the programmable storage unit 301 are stabilized. The programmable storage unit 301 may start performing the boot-up operation as early as possible after the memory device is turned on. This is because the memory device may perform a normal operation when the boot-up operation is completed. In order for the programmable storage unit 301 to normally operate, at least the levels of the powers VDD, VPP, VBB, and VDIV used in the programmable storage unit 301 have to be stabilized. This is because the stable boot-up operation itself of the programmable storage unit 301 may not be possible when the powers VDD, VPP, VBB, and VDIV are not yet stabilized. The activation of the power stabilization signal POWER_SAFE generated in the voltage detection unit 320 means that at least the powers VDD, VPP, VBB, and VDIV used in the programmable storage unit 301 are stabilized.

The boot-up control unit 330 counts the number of activations of a periodic wave from the time of the activation of the power stabilization signal POWER_SAFE. When the counted number reaches a preset number, the boot-up control unit 330 activates the boot-up enable signal BOOTEN. That is, the boot-up control unit 330 counts the predetermined number of cycles of a periodic wave. The boot-up control unit 330 performs control such that the boot-up operation may start after elapse of a time predetermined to ensure a margin after the activation of the power stabilization signal POWER_SAFE.

The voltage detection unit 320 and the boot-up control unit 330 cause the boot-up operation to be performed as early as possible for a stable operation by controlling the boot-up operation such that the boot-up operation starts after the stabilization of the powers VDD, VPP, VBB, and VDIV used in the programmable storage unit 301 and the elapse of the time predetermined to ensure the margin. Since the boot-up enable signal BOOTEN is generated internally without use of a control signal inputted from the outside of the memory device, the memory device may not be required to receive an input of a separate signal used for the boot-up operation.

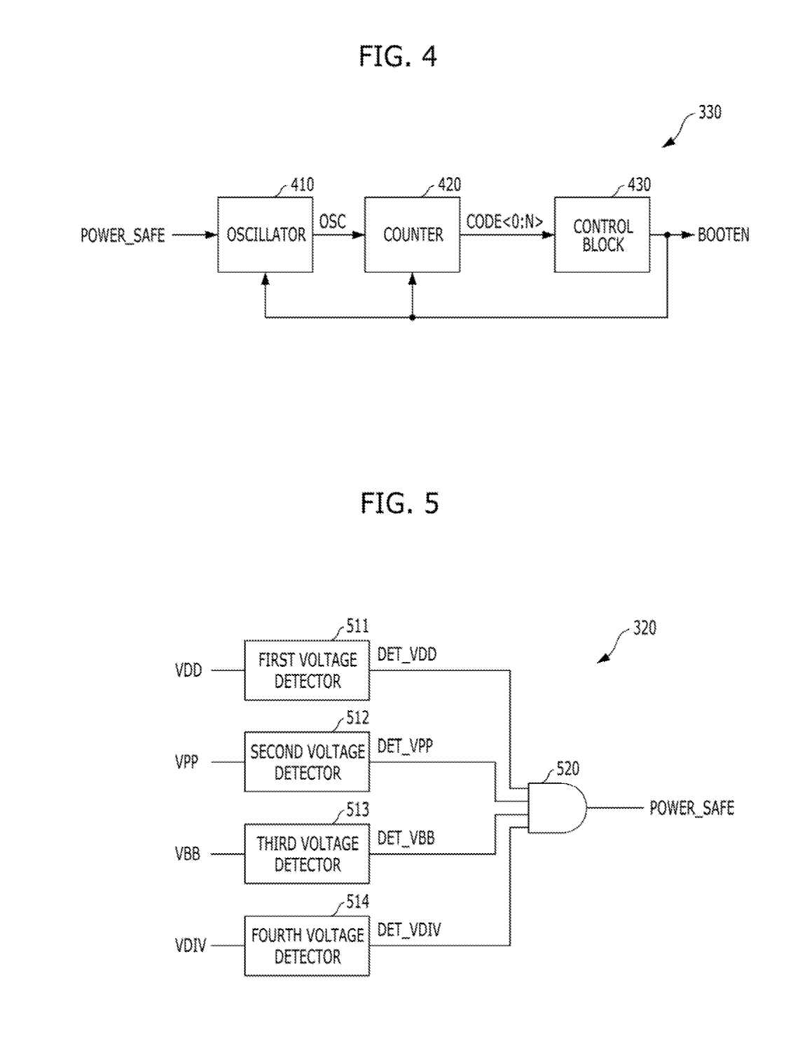

FIG. 4 is a detailed diagram illustrating the boot-up control unit 330 shown in FIG. 3.

Referring to FIG. 4, the boot-up control unit 330 may include an oscillator 410, a counter 420, and a control block 430.

The oscillator 410 generates a periodic wave OSC in response to the activation of the power stabilization signal POWER_SAFE. That is, the periodic wave starts toggle after the activation of the power stabilization signal POWER_SAFE. The boot-up enable signal BOOTEN may be used as a reset signal of the oscillator 410. When the boot-up enable signal BOOTEN is activated, the oscillator 410 may inactivate the periodic wave OSC. That is, when the boot-up enable signal BOOTEN is activated, the toggle of the periodic wave OSC may stop. In general, the memory device includes an oscillator that operates a self-refresh operation. The oscillator 410 of the boot-up control unit 330 may be used as the oscillator that performs the self-refresh operation.

The counter 420 generates a code CODE <0:N> by counting the number of activations of the periodic wave OSC. The code CODE <0:N> may be a binary code of N+1 bits. The counter 420 increases the value of the code CODE <0:N> by one, whenever the periodic wave OSC is activated. The code CODE <0:N> may be reset in response to the activation of the boot-up enable signal BOOTEN. That is, when the boot-up enable signal BOOTEN is activated, the value of the code CODE <0:N> may be initialized, for example, to ‘00000000’.

The control block 430 activates the boot-up enable signal BOOTEN, when the code CODE <0:N> reaches a preset value. For example, when the preset value is ‘200’ and the value of the code CODE <0: N> reaches ‘200’ which is a value converted into a decimal number, the boot-up enable signal BOOTEN is activated. The preset value may differ according to whether a given time is ensured as a margin after the activation of the power stabilization signal POWER_SAFE and the boot-up operation starts. The larger the preset value is, the larger the margin is. The smaller the preset value is, the smaller the margin is.

FIG. 5 is a detailed diagram illustrating the voltage detection unit 320 shown in FIG. 3.

Referring to FIG. 5, the voltage detection unit 320 may include first to fourth voltage detectors 511 to 514 and a signal generation block 520.

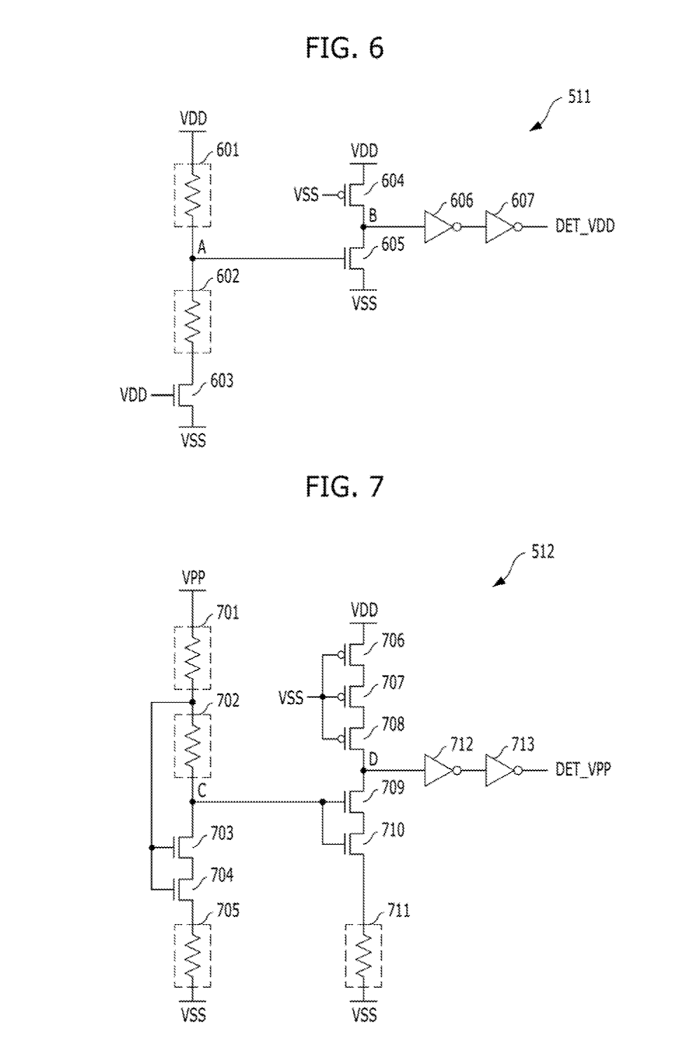

The first to fourth voltage detectors 511 to 514 generate detection signals DET_VDD, DET_VPP, DET_VBB, and DET_VDIV activated when the levels of the powers VDD, VPP, VBB, and VDIV reach target voltages. The target voltages may be set to be slightly lower than the levels of the powers VDD, VPP, VBB, and VDIV in a steady state. For example, when the voltage level of the steady state of the boosted voltage VPP is 4 V, the second voltage detector 512 may activate the detection signal DET_VPP, when the level of the boosted voltage VPP reaches 3.5 V. For example, the third voltage detector 513 may activate the detection signal DET_VBB, when the voltage level of the steady state of the negative voltage VBB is −2 V. The configurations of the first to fourth voltage detectors 511 to 514 will be described in more detail with reference to FIGS. 6 to 8.

The signal generation block 520 activates the power stabilization signal POWER_SAFE, when all of the detection signals DET_VDD, DET_VPP, DET_VBB, and DET_VDIV are activated. The signal generation block 520 may include end-gates, as in the drawing.

FIG. 6 is a detailed diagram illustrating the first voltage detector 511 shown in FIG. 5.

Referring to FIG. 6, the first voltage detector 511 includes NMOS transistors 603 and 505, a PMOS transistor 604, resistors 601 and 602, and inverters 606 and 607. The first voltage detector 511 detects the level of the source voltage VDD based on the source voltage VDD. Such a circuit is well known as a power-up circuit.

In an operation of the first voltage detector 511, the NMOS transistor 603 is turned off when the level of the source voltage VDD is low. Therefore, the voltage level of node A increases, and thus the NMOS transistor 605 is turned on. Consequently, the voltage level of node B decreases and the detection signal DET_VDD is inactivated to be a logic low level. However, the level of the source voltage VDD increases to a level equal to or greater than a given level, the NMOS transistor 603 is turned on, the voltage level of node A decreases, and thus the NMOS transistor 605 is turned off. Consequently, the voltage level of node B increases and the detection signal DET_VDD is activated to be a logic high level.

FIG. 7 is a detailed diagram illustrating the second voltage detector 512 shown in FIG. 5.

Referring to FIG. 7, the second voltage detector 512 includes resistors 701, 702, 705, and 711, NMOS transistors 703, 704, 709, and 710, PMOS transistors 706, 707, and 708, and inverters 712 and 713.

When the level of the boosted voltage VPP is low, the NMOS transistors 703 and 704 are turned off, the voltage level of node C increases, and thus the NMOS transistors 709 and 710 are turned on. Consequently, the voltage level of node D decreases, and thus the detection signal DET_VPP is inactivated to be a logic low level. When the level of the boosted voltage VPP sufficiently increases, the NMOS transistors 703 and 704 are turned on, the voltage level of node C decreases, and thus the NMOS transistors 709 and 710 are turned off. Consequently, the voltage level of node D increases, and thus the detection signal DET_VPP is activated to be a logic high level.

Meanwhile, the fourth voltage detector 514 may have the same configuration as the first voltage detector 511 shown in FIG. 6 or the second voltage detector 512 shown in FIG. 7. However, parameters of transistors and resistors are changed and designed so as to be suitable for the level of the divided voltage VDIV detected by the fourth voltage detector 514.

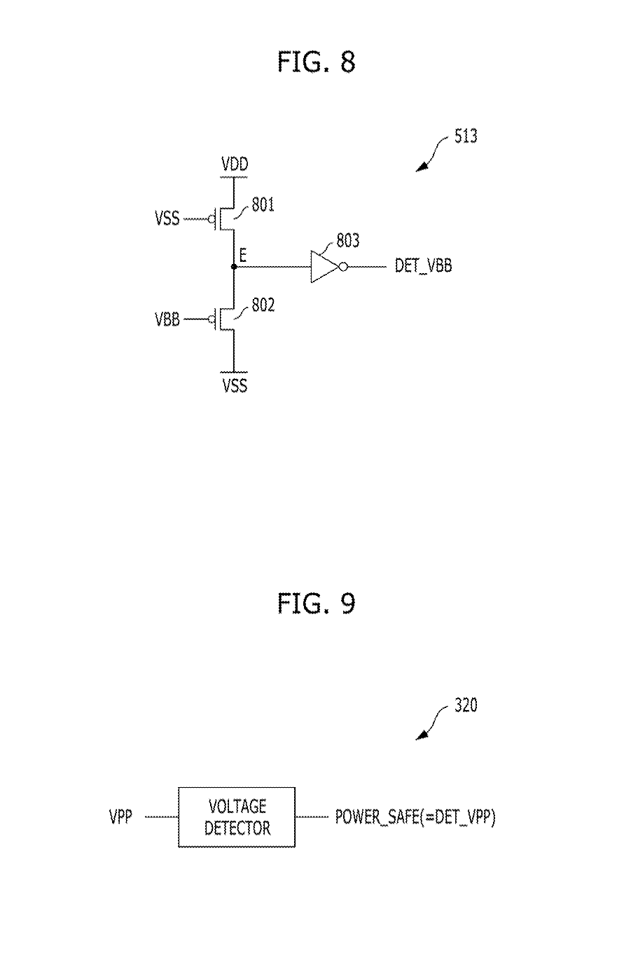

FIG. 8 is a detailed diagram illustrating the third voltage detector 513 shown in FIG. 5.

Referring to FIG. 8, the third voltage detector 513 includes PMOS transistors 801 and 802 and an inverter 803.

When the absolute value of the negative value VBB is small (that is, the level of the negative voltage is high), the resistance value of the PMOS transistor 802 increases. Therefore, the voltage of node E increases, and thus the detection signal DET_VBB is outputted as a logic low level signal. When the absolute value of the negative voltage VBB is large (that is, the level of the negative voltage is low), the resistance value of the PMOS transistor 802 decreases. Therefore, the voltage of node E decreases, and thus the detection signal DET_VBB is outputted as a logic high level signal.

In FIGS. 6 to 8, the configurations of the voltage detectors 511 to 514 have been described. Not only the circuits illustrated in FIGS. 6 to 8 but also various types of circuits for detecting the levels of the voltages may, of course, be used as the voltage detectors 511 to 514.

FIG. 9 is a detailed diagram illustrating the voltage detection unit 320 shown in FIG. 3.

Referring to FIG. 9, an embodiment will be described in which only the level of one power (or one voltage) VPP is detected among the powers VDD, VPP, VBB, and VDIV used in the programmable storage unit 301 and the power stabilization signal POWER_SAFE is generated. When the power VPP that is the highest likely to be stabilized most lately among the powers VDD, VPP, VBB, and VDIV is stabilized, all of the other powers are assumed to be stabilized. Therefore, the embodiment as in FIG. 9 may be realized.

Referring to FIG. 9, the voltage detection unit 320 may include one voltage detector, for example, the second voltage detector 512 shown in FIG. 7. The detection signal DET_VPP itself generated by the voltage detector may serve as the power stabilization signal POWER_SAFE.

In the embodiment of FIG. 9, the example has been described in which the level of the boosted voltage VPP is detected among the powers VDD, VPP, VBB, and VDIV and the power stabilization signal POWER_SAFE is generated. However, an embodiment may, of course, be implemented in which the level of the negative voltage VBB is detected among the powers VDD, VPP, VBB, and VDIV and the power stabilization signal POWER_SAFE is generated. This is because the negative voltage VBB is a voltage that is stabilized most lately among the powers VDD, VPP, VBB, and VDIV. In the embodiment of FIG. 5, the example has been described in which the levels of the four voltages VDD, VPP, VBB, and VDIV are detected and the power stabilization signal POWER_SAFE is generated. In the embodiment of FIG. 9, the example has been described in which the level of one voltage VPP is detected and the power stabilization signal POWER_SAFE is generated. However, of course, the levels of two or three voltages may be detected and the power stabilization signal POWER_SAFE may be generated.

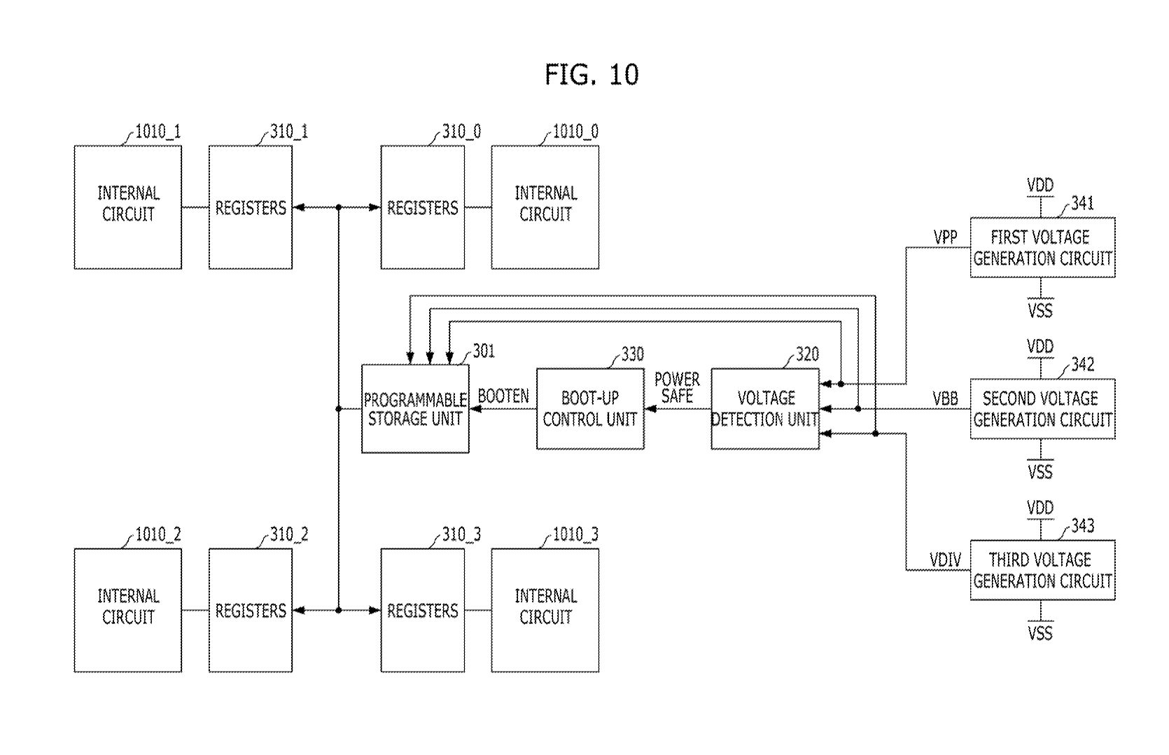

FIG. 10 is a block diagram illustrating an integrated circuit according to another embodiment of the present invention.

As illustrated in FIG. 10, the present invention may be applied not only to the memory device but also all kinds of integrated circuits. Referring to FIG. 10, an integrated circuit may include the programmable storage unit 301, the plurality of register units 310_0 to 310_3, a plurality of internal circuits 1010_0 to 1010_3, the voltage detection unit 320, the boot-up control unit 330, and the first to third voltage generation circuits 341 to 343.

The programmable storage unit 301 operates using a plurality of powers VDD, VSS, VPP, VBB, and VDIV and outputs stored data in response to a boot-up enable signal BOOTEN. The programmable storage unit 301 stores information, for example, various kinds of setting or tuning information, necessary for operations of the plurality of internal circuits 1010_0 to 1010_3 and transmits information stored at the time of a boot-up operation to the plurality of register units 310_0 to 310_3.

The internal circuits 1010_0 to 1010_3 are circuits that operate using information transmitted from the programmable storage unit 301 to the plurality of register units 310_0 to 310_3 among the circuits present inside the integrated circuit. When the internal circuit 1010_0 is a voltage generation circuit, the internal circuit 1010_0 may adjust the level of a voltage generated by the own internal circuit using the information stored in the register units 310_0. When the internal circuit 1010_1 is a delay circuit, the internal circuit 1010_1 may adjust a delay value of the own internal circuit using the information stored in the register unit 310_1. When the internal circuit 1010_2 is a circuit that sets an operation mode of the integrated circuit, the internal circuit 1010_2 may set the operation mode of the integrated circuit using mode information stored in the register unit 310_2. Thus, the internal circuits 1010_0 to 1010_3 may be configured as any circuit that operates using the information stored in the programmable storage unit 301 inside the integrated circuit.

In the embodiment of FIG. 10, the example in which the present invention is applied not to a memory device but to a general integrated circuit is merely illustrated. Since the details relevant to the determination of the boot-up time are the same as those described in FIGS. 3 to 9, the detailed description thereof will be omitted.

According to the embodiments, the boot-up operation may be performed at an optimum time.

Although various embodiments have been described for illustrative purposes, it will be apparent to those skilled in the art that various changes and modifications may be made without departing from the spirit and scope of the invention as defined in the following claims.

What is claimed is:

1. An integrated circuit comprising:
a programmable storage unit suitable for operating with a plurality of powers and outputting data stored in the programmable storage unit in response to a boot-up signal;
a register unit suitable for storing the data outputted from the programmable storage unit;
an internal circuit suitable for operating by using the data stored in the register unit;
a voltage detection unit suitable for activating a power stabilization signal when levels of the plurality of powers are stabilized; and
a boot-up control unit suitable for counting a number of activations of a periodic wave from a time of an activation of the power stabilization signal and activating the boot-up signal when the counted number reaches a predetermined number.

2. The integrated circuit of claim wherein the voltage detection unit includes:
a plurality of voltage detectors suitable for detecting voltage levels of the plurality of powers and generating a plurality of detection signals to be activated when the voltage levels of the plurality of powers reach target voltages, respectively; and
a signal generation block suitable for activating the power stabilization signal when all of the plurality of detection signals are activated.

3. The integrated circuit of claim 1, wherein the voltage detection unit includes a voltage detector suitable for activating the power stabilization signal, when a level of a predetermined power among the plurality of powers reaches a target voltage.

4. The integrated circuit of claim 3, wherein the predetermined power is a power stabilized most lately among the plurality of powers.

5. The integrated circuit of claim 1, wherein the boot-up control unit includes:
an oscillator suitable for generating the periodic wave in response to the power stabilization signal,
a counter suitable for generating a code by counting the number of activations of the periodic wave; and
a control block suitable for activating the boot-up signal when the code reaches a preset value.

6. The integrated circuit of claim 1, wherein the plurality of powers include at least two of a source voltage applied from the outside of the integrated circuit, a divided voltage generated by dividing the source voltage, a boosted voltage generated by pumping the source voltage, and a negative voltage generated by pumping a ground voltage.

7. The integrated circuit of claim 1, wherein the programmable storage unit includes one of an e-fuse array circuit, a NAND flash memory, a NOR flash memory, an erasable programmable ROM, an electrically erasable programmable ROM, a ferroelectric RAM, a magnetoresistive RAM, a spin transfer torque MRAM, a resistive RAM, and a phase change RAM.

8. A memory device comprising:
a programmable storage unit suitable for operating with a plurality of powers and outputting stored repair information in response to a boot-up signal;
a plurality of register units suitable for storing the repair information outputted from the programmable storage unit;
a plurality of memory banks having a plurality of normal cells and a plurality of redundancy cells, in which a defective cell included in the plurality of normal cells is substituted with one of the redundancy cells using the repair information stored in the respective register units;
a voltage detection unit suitable for activating a power stabilization signal when levels of the plurality of powers are stabilized; and
a boot-up control unit suitable for counting a number of activations of a periodic wave from a time of an activation of the power stabilization signal and activating the boot-up signal when the counted number reaches a predetermined number.

9. The memory device of claim 8, wherein the voltage detection unit includes:
a plurality of voltage detector suitable for detecting voltage levels of the plurality of powers and generating a plurality of detection signals to be activated when the voltage levels of the plurality of powers reach target voltages, respectively; and
a signal generation block suitable for activating the power stabilization signal when all of the plurality of detection signals are activated.

10. The memory device of claim 8, wherein the voltage detection unit includes a voltage detector suitable for activating the power stabilization signal, when a level of a predetermined power among the plurality of powers reaches a target voltage.

11. The memory device of claim 10, wherein the predetermined power is a power stabilized most lately among the plurality of powers.

12. The memory device of claim 8, wherein the boot-up control unit includes:
an oscillator suitable for generating the periodic wave in response to the power stabilization signal;
a counter suitable for generating a code by counting the cycles of the periodic wave; and
a control block suitable for activating the boot-up signal when the code has a predetermined value.

13. The memory device of claim 8, wherein the plurality of powers include at least two of a source voltage applied from the outside of the memory device, a divided voltage generated by dividing the source voltage, a boosted voltage generated by pumping the source voltage, and a negative voltage generated by pumping a ground voltage.

14. The memory device of claim 8, wherein the programmable storage unit includes one of an e-fuse array circuit, a NAND flash memory, a NOR flash memory, an erasable programmable ROM, an electrically erasable programmable ROM, a ferroelectric RAM, a magnetoresistive RAM, a spin transfer torque MRAM, a resistive RAM, and a phase change RAM.

15. An integrated circuit comprising:
a programmable storage unit suitable for performing a boot-up operation using an internal voltage in response to a boot-up enable signal;
a voltage detection unit suitable for detecting a level of the internal voltage to generate a power stabilization signal; and
a boot-up control unit suitable for generating the boot-up enable signal by counting a number of cycles of a periodic wave having a predetermined frequency in response to the power stabilization signal, wherein the boot-up enable signal is activated when the number of cycles reaches a predetermined numbers.

16. The integrated circuit of claim 15, wherein the boot-up control unit includes:
an oscillator suitable for generating the periodic wave in response to the power stabilization signal;
a counter suitable for generating a code corresponding to the number of cycles; and
a control block suitable for activating the boot-up signal when the code has a predetermined value.

17. The integrated circuit of claim 15, wherein the programmable storage unit includes one of an e-fuse array circuit, a NAND flash memory, a NOR flash memory, an erasable programmable ROM, an electrically erasable programmable ROM, a ferroelectric RAM, a magnetoresistive RAM, a spin transfer torque MRAM, a resistive RAM and a phase change RAM.

18. The integrated circuit of claim 15, wherein the programmable storage unit includes repair information which is programmed in the programmable storage unit.
